(19) United States
(12) Patent Application Publication
(10) Pub. No.: US 2012/0104530 A1
(43) Pub. Date: May 3, 2012

(54) SUBSTRATE FOR DISPLAY PANEL, AND DISPLAY DEVICE

(75) Inventors: Seiji Kaneko, Osaka-shi (JP); Masahiro Fujiwara, Osaka-shi (JP); Hiroshi Aichi, Osaka-shi (JP); Noboru Takeuchi, Osaka-shi (JP)

(73) Assignee: Sharp Kabushiki Kaisha, Osaka-shi (JP)

(21) Appl. No.: 13/378,617

(22) PCT Filed: Feb. 18, 2010
(86) PCT No.: PCT/JP10/01035

§ 371 Date: Dec. 15, 2011

(30) Foreign Application Priority Data
Jun. 16, 2009 (JP) 2009-143446

(51) Int. Cl. H01L 27/146

(52) U.S. Cl. 257/433; 257/E27.133

(57) ABSTRACT

A display panel substrate includes a plurality of pixels, a pixel in the display panel substrate including a PIN diode for conducting therethrough a different electric current in accordance with an amount of light received by the light receiving element, a first inorganic insulating film formed on the PIN diode, a line formed on or above the first inorganic insulating film and electrically connected to the PIN diode, an organic insulating film formed on or above the line, a transparent pixel electrode formed on the organic insulating film, and a transparent cover electrode provided at such a position that the transparent electrode is located between the organic insulating film and the first inorganic insulating film and formed to cover at least a part of an I-layer of the PIN diode.

### REFERENCE TO RELATED APPLICATIONS

This application is the national stage under 35 USC 371 of International Application No. PCT/JP2010/001035, filed Feb. 18, 2010, which claims the priority of Japanese Patent Application No. 2009-143446, filed Jun. 16, 2009, the entire contents of which are incorporated herein by reference.

### TECHNICAL FIELD

The present invention relates to a display panel substrate including a light receiving element (optical sensor) and a display device including the display panel substrate.

### BACKGROUND ART

In recent years, there has been developed a display device in which a plurality of optical sensors are arranged at regular intervals in a display region of the display device including a plurality of pixels, and each optical sensor is provided in a corresponding pixel. Such display devices have regular display functions, and in addition, a touch panel function (area sensor function) etc. with use of a light detection function of the optical sensors. When a panel surface is touched with a stylus pen, a human finger, or the like, the touch panel function detects a location of the touch within the panel surface.

Examples of such optical sensors provided in the display device encompass a PIN photodiode and the like. The PIN photodiode has the following two structures: a vertical structure in which a P-layer, an I-layer, and an N-layer are laminated on a substrate in this order; and a lateral structure in which the P-layer, the I-layer, the N-layer are aligned to one another along an in-plane direction. Note that the P-layer is a semiconductor layer having a high P-type impurity concentration, the I-layer is an intrinsic semiconductor or a semiconductor layer having a low impurity concentration, and the N-layer is a semiconductor layer having a high N-type impurity concentration.

The lateral structure, in which the P-layer, the I-layer, and the N-layer are not laminated over each other, has a low parasitic capacitance between any two layers, and therefore has a higher sensing speed than the vertical structure. Because of this advantage, the lateral structure is generally used.

Further, the lateral structure can be easily manufactured by the same process as other elements etc. formed on the substrate.

For example, Patent Literature 1 discloses a liquid crystal display device including a PIN photodiode serving as an optical sensor.

The liquid crystal display device is described below with reference to FIG. 15. Light shielding films 141 and 142 are formed on an element forming surface 114a of an array substrate 114. The light shielding film 141 shields light L1 incident on a TFT element 150 of a display section 123 from a backlight, and the light shielding film 142 shields the light L1 incident on a PIN photodiode (PIN diode) 145 of a light receiving section 124 from the backlight.

An insulating film 143 constituted by a silicon oxide film and the like is deposited on both the light shielding films 141 and 142 so as to cover substantially all the surface of the element forming surface 114a.

A semiconductor layer 144 (a P-type channel region 144c, an N-type source region 144s, and an N-type drain region 144d) constituting the TFT element 150 are formed on a top surface of the insulating film 143 so as to be positioned above the light-shielding film 141.

Further, a PIN diode 145 (an I-type region 145i, an N-type region 145n, and a P-type region 145p of a polycrystalline semiconductor) serving as an optical sensor are formed on the top surface of the insulating film 143 so as to be positioned above the light-shielding film 142.

A gate insulating film 146 constituted by a silicon oxide film and the like is deposited on the semiconductor layer 144 and the PIN diode 145 so as to cover substantially all the surface of the element forming surface 114a. A gate electrode 147 is formed on a top surface of the gate insulating film 146 so as to be positioned above the channel region 144c of the semiconductor layer 144.

A first interlayer insulating film 151 constituted by a silicon oxide film and the like is formed on the gate electrode 147 so as to cover the gate insulating film 146.

Further, a contact hole H1 is perforated in a source region 144s of the semiconductor layer 144, meanwhile, a contact hole H2 is perforated in a drain region 144d thereof. The source region 144s electrically connected to a data line Ly is formed in the contact hole H1, and the drain region 144d electrically connected to a drain electrode 152 is formed in the contact hole H2.

A contact hole H3 is perforated in the N-type region 145n of the PIN diode 145, meanwhile, a contact hole H4 is perforated in the P-type region 145p thereof. The N-type region 145n electrically connected to a first electrode 153 is formed in the contact hole H3, and the P-type region 145p electrically connected to a second electrode 154 is formed in the contact hole H4.

A second interlayer insulating film 155 constituted by a silicon oxide film and the like is formed on the data line Ly, the drain electrode 152, and the first and second electrodes 153, 154 so as to cover the first interlayer insulating film 151. An organic planarizing film 156 made of acrylic resin etc. is formed on the second interlayer insulating film 155.

A via hole 158 is formed above the drain electrode 152. A pixel electrode 159 made of an optical-transparent conductive material (e.g., ITO) is provided inside the via hole 158 and on a cholesteric liquid crystal layer 157 of each pixel. The cholesteric liquid crystal layer 157 is provided above a region in which the PIN diode 145 is formed. Note that the pixel electrode 159 is connected to the drain electrode 152 through the via hole 158.

The array substrate 114 and a color filter substrate 115 including a filter layer 133 of respective colors (only a red color filter layer 133R is illustrated in FIG. 15) are arranged so that the pixel electrode 159 and a counter electrode 161 face each other. A nematic liquid crystal 117 is sandwiched between the pixel electrode 159 and the counter electrode 161.

According to the aforementioned arrangement, the organic planarizing film 156 having relatively low dielectric constant is provided between the pixel electrode 159 and the signal lines such as the data line Ly. It is therefore possible to reduce a capacitance of a parasitic capacitor.

Further, the pixel electrode 159 and the signal lines can be superimposed to each other, or the cholesteric liquid crystal layer 157 provided above the PIN diode 145 can reflect only light having a specified wavelength (red light Lr). This makes it possible to accomplish a liquid crystal display device having an improved aperture ratio and an improved use efficiency of light.

Patent Literature 2 discloses a technique by which polarization, which is caused by water in a liquid crystal or water leaked into the liquid crystal through a gap of a seal agent, can be prevented by reducing a relative dielectric constant of a planarizing film formed on a TFT element. In particular, Patent Literature 2 discloses that the polarization can be prevented with use of substances having a relative dielectric constant of five or less, and preferably, four or less.

Patent Literature 3 discloses an arrangement that can prevent a separation phenomena between an organic film and an inorganic film. The separation phenomena is prevented by arranging such that the inorganic film is an inorganic insulating film having surfaces different from each other, i.e., there is a difference between one surface in contact with the organic protection film and the other surface in no contact therewith (for example, only one surface of the inorganic insulating film, which is in contact with an organic protection film, is uneven).

Citation List

Patent Literatures

Patent Literature 1
Japanese Patent Application Publication, Tokukai, No. 2008-158272 A (Publication Date: Jul. 10, 2008)

Patent Literature 2
Japanese Patent Application Publication, Tokukaihei, No. 11-274510 A (Publication Date: Oct. 8, 1999)

Patent Literature 3
Japanese Patent Application Publication, Tokukai, No. 2007-116164 A (Publication Date: May 10, 2007)

### SUMMARY OF INVENTION

However, the inventors of the present invention found that the arrangement of Patent Literature 1 had a problem with reliability because a photocurrent characteristic of the PIN diode 145 was deteriorated in the case where the PIN diode 145 serving as an optical sensor formed on the array substrate 114 was driven for a long time.

It considered that a voltage applied to the pixel electrode 159 causes the electric charges to be accumulated in the organic planarizing film 156, so that the electric charges have the adverse effect on the PIN diode 145 due to the capacitive coupling.

Further, the organic insulating film (organic planarizing film) having the relative dielectric constant of four or less, which is described in Patent Literature 2, is already generalized. Accordingly, such organic insulating film (organic planarizing film) cannot solve the problem of reliability.

Further, the arrangement described in Patent Literature 3 can prevent the separation phenomena of the organic film and inorganic film, however, the arrangement cannot solve the problem of reliability.

The present invention has been made in view of the aforementioned problems, and an object of the present invention is to provide (i) a display panel substrate including a light receiving element (optical sensor) that has reliability improved by reducing deterioration of a photocurrent characteristic even when an organic insulating film (organic planarizing film) is used and (ii) a display device including the display panel substrate.

In order to attain the object, a display panel substrate of the present invention includes a plurality of pixels, the display panel substrate including, in a pixel: a light receiving element for flowing therethrough a different electric current in accordance with an amount of light received by the light receiving element, a first inorganic insulating film formed on or above the light receiving element, a line, being formed on or above the first inorganic insulating film and being electrically connected to the light receiving element, an organic insulating film formed on or above the line, a transparent pixel electrode formed on or above the organic insulating film, and a transparent electrode, which is provided at such a position that the transparent electrode is located between the organic insulating film and the first inorganic insulating film so as to cover at least a part of a light receiving section of the light receiving element.

The aforementioned arrangement has such a feature that the organic insulating film is provided between the lines and the transparent pixel electrode, so that capacitance of a parasitic capacitor, which is generated between the lines and the transparent pixel electrode, can be reduced.

However, simply with this feature as described above, electric charges would be accumulated in the organic insulating film due to a voltage applied to the transparent pixel electrode. This accumulation of the electric charges causes capacitive coupling and deteriorates a photocurrent characteristic of the light receiving element as described above.

In view of the circumstances, in the arrangement of the present invention further have such a feature that the transparent electrode for applying a predetermined voltage is provided between the organic insulating film and the light receiving element, more specifically, at such a position that the transparent electrode is located between the organic insulating film and the first inorganic insulating film so as to cover at least a part of the light receiving section of the light receiving element. This arrangement makes it possible to reduce an adverse effect on the light receiving section of the light receiving element, which adverse effect is caused by the capacitive coupling of the electric charges accumulated in the organic insulating film.

Therefore, the present invention can accomplish a display panel substrate including a light receiving element that has reliability improved by reducing deterioration of the photocurrent characteristic of the light receiving element even in the case where the display panel substrate includes an organic insulating film and the light receiving element is driven for a long time.

Further, the transparent electrode provided above the light receiving section of the light receiving element is optically transparent, so that a light receiving area of the light receiving element is not reduced.

Note that the organic insulating film means an insulating film containing an organic substance as a base, and is, for example, an insulating film containing only an organic substance or an insulating film added with an inorganic substance as necessary.

In order to attain the object, the display panel substrate of the present invention includes a light receiving element for flowing therethrough a different electric current in accordance with an amount of light received by the light receiving element; an organic insulating film formed on a light path of the light incident on the light receiving element; and a transparent electrode formed on the light path so as to be between the light receiving element and the organic insulating film.

According to the aforementioned arrangement, the transparent electrode is formed on the light path so as to be between the light receiving element and the organic insulating film. This arrangement makes it possible to reduce an adverse effect on the light receiving section of the light receiving element, which adverse effect is caused by the capacitive coupling of the electric charges accumulated in the organic insulating film.

Therefore, the present invention can accomplish a display panel substrate including a light receiving element that has reliability improved by reducing deterioration of the photocurrent characteristic of the light receiving element even in the case where the display panel substrate includes an organic insulating film and the light receiving element is driven for a long time.

In order to attain the object, a display device of the present invention includes the display panel substrate.

According to the aforementioned arrangement, the display device includes the display panel substrate including the light receiving element, so that the present invention can accomplish a high-reliable display device that has a bright display quality and a touch panel function (area sensor function).

As described above, a display panel substrate of the present invention includes a light receiving element for flowing therethrough a different electric current in accordance with an amount of light received by the light receiving element, a first inorganic insulating film formed on or above the light receiving element, a line, being formed on or above the first inorganic insulating film and being electrically connected to the light receiving element, an organic insulating film formed on or above the line, a transparent pixel electrode formed on or above the organic insulating film, and a transparent electrode, which is provided at such a position that the transparent electrode is located between the organic insulating film and the first inorganic insulating film so as to cover at least a part of a light receiving section of the light receiving element.

Further, the display panel substrate of the present invention includes: a light receiving element for flowing therethrough a different electric current in accordance with an amount of light received by the light receiving element; an organic insulating film formed on a light path of the light incident on the light receiving element; and a transparent electrode formed on the light path so as to be between the light receiving element and the organic insulating film.

Further, a display device of the present invention includes the display panel substrate as described above.

Accordingly, the present invention makes it possible to accomplish a display panel substrate including a light receiving element (optical sensor) that has reliability improved by reducing deterioration of a photocurrent characteristic even when an organic insulating film (organic planarizing film) is used.

Further, the present invention also makes it possible to accomplish a high-reliable display device that has a bright display quality and a touch panel function (area sensor function).

### BRIEF DESCRIPTION OF DRAWINGS

FIG. 1

FIG. 1 is a cross sectional view illustrating a schematic arrangement of a liquid crystal display device including a display panel substrate of Embodiment 1 of the present invention.

FIG. 2

FIG. 2 is a plan view illustrating a PIN diode provided in the display panel substrate of FIG. 1, seen from a side on which a transparent cover electrode is formed.

FIG. 3

FIG. 3(a) is a cross sectional view taken along the line A-A′ of FIG. 2; and FIG. 3(b) is a cross sectional view of a comparative example illustrating a portion which corresponds to FIG. 3(a).

FIG. 4

FIG. 4(a) is a view illustrating ambient temperature dependence of a leakage current in an organic insulating film; FIG. 4(b) is a view illustrating ambient temperature dependence of a leakage current in an inorganic insulating film.

FIG. 5

FIG. 5 is a graph showing a change over time in a photocurrent characteristic of a PIN diode included in a display panel substrate of the comparative example illustrated in FIG. 3(b).

FIG. 6

FIG. 6 is a graph showing a change over time in a photocurrent characteristic of a PIN diode included in a display panel substrate Embodiment 1 illustrated in FIG. 3(a).

FIG. 7

FIG. 7 is a view illustrating a measurement condition for measuring voltage dependence of a photocurrent in a PIN diode.

FIG. 8

FIG. 8 is a graph showing voltage dependence of a photocurrent in a PIN diode.

FIG. 9

FIG. 9 is a circuit diagram illustrating an example of a circuit arrangement of one pixel unit constituted by red, green, and blue pixels in the display panel substrate of FIG. 1.

FIG. 10

FIG. 10 is a circuit diagram illustrating another example of a circuit arrangement of one pixel unit constituted by red, green, and blue pixels in the display panel substrate of FIG. 1.

FIG. 11

FIG. 11 is a view illustrating an example in which, in the circuit arrangement of FIG. 10, a transparent cover electrode bus line is formed along a direction in which a reset signal line and a row selection signal line extend.

FIG. 12

FIG. 12 is a view illustrating an example in which, in the circuit arrangement of FIG. 10, a transparent cover electrode bus line is formed along a direction in which a source signal line (power source supply line) and a source signal line (output signal line) extend.

FIG. 13

FIG. 13 is a plan view illustrating a PIN diode provided in the display panel substrate of Embodiment 2, seen from a side on which a transparent cover electrode is formed.

FIG. 14

FIG. 14 is a cross sectional view taken along the line B-B′ of FIG. 13.

FIG. 15

FIG. 15 is a cross sectional view illustrating principal parts of a display section and a light receiving section of a pixel in a conventional liquid crystal display device.

### DETAILED DESCRIPTION OF THE INVENTION

Embodiments of the present invention will be described below in detail with reference to the drawings. Note that size, material, shape, and the way of relative positions of each member described in the present embodiments are merely examples, and therefore the scope of the invention should not be interpreted as being limited by these embodiments.

### Embodiment 1

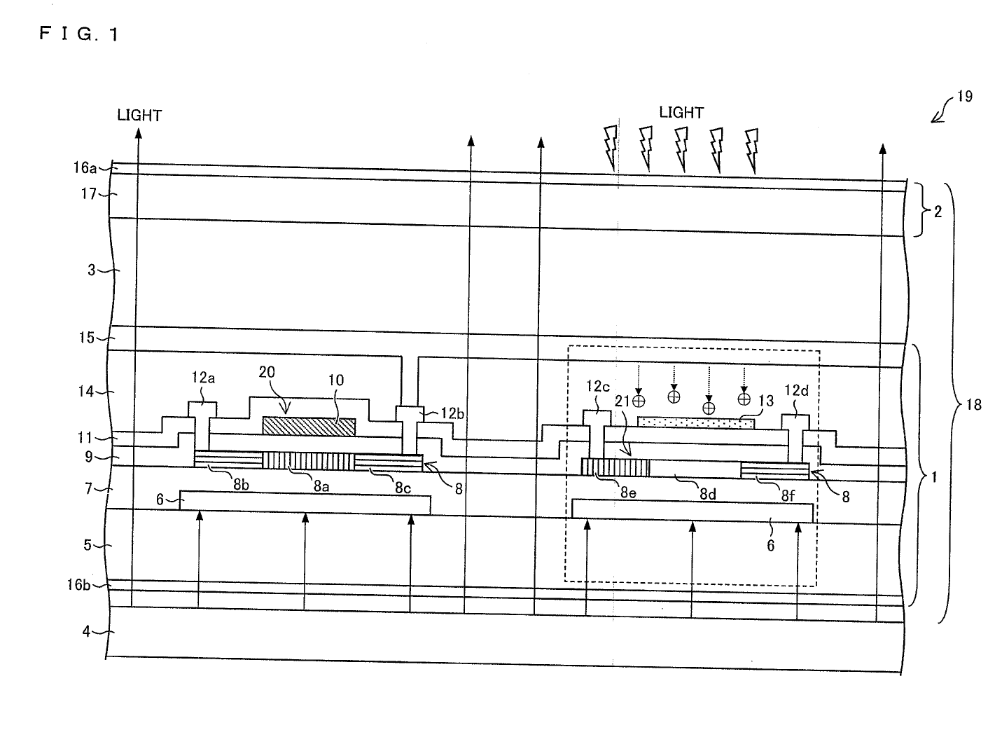

An arrangement of an active matrix substrate 1 (serving as a display panel substrate of the present invention) and a liquid crystal display device 19 (serving as a display device) will be described below with reference to FIGS. 1 through 12.

Note that a display device of the present invention is not limited to the crystal display device 19 and, for example, the present invention can be accomplished with use of an organic electroluminescence display device instead.

As illustrated in FIG. 1, the liquid crystal display device 19 includes the active matrix substrate 1, a color filter substrate 2 facing the active matrix substrate 1, and a liquid crystal display panel 18 in which a liquid crystal layer 3 is sandwiched between these substrates 1 and 2 in a state of being sealed by a sealing material.

The liquid crystal display device 19 further includes a backlight unit 4 for irradiating the liquid crystal display panel 18 with light.

Note that a color filter layer, a common electrode, an alignment film, and the like (all not illustrated) are formed on a glass substrate 17 of the color filter substrate 2, and a polarization plate 16a is provided on an opposite side of a surface on which the color filter layer is formed.

Meanwhile, a polarization plate 16b is provided on a side of a surface of the active matrix substrate 1, which surface faces the backlight unit 4.

The arrangement of the active matrix substrate 1 will be described below in detail.

The active matrix substrate 1 includes a display region including a plurality of transparent pixel electrodes 15 arranged in a matrix manner.

As illustrated in FIG. 1, a pixel TFT 20 serving as an active element for controlling the transparent pixel electrode 15 and a PIN diode 21 serving as a light receiving element for accomplishing a touch panel function are included in a region in which a transparent pixel electrode 15 is formed.

According to the aforementioned arrangement, the pixel TFT 20 can apply on the transparent pixel electrode 15 a voltage for displaying a desired image, and the PIN diode 21 causes an electric current to pass through the PIN diode 21 in such a manner that the electric current has a different ampere value depending on an amount of light received by the PIN diode 21, so that touching the display panel with a finger, a pen, or the like can be detected.

The aforementioned liquid crystal display device 19 with the touch panel function (area sensor function), which includes the active matrix substrate 1 in which the pixel TFTs 20 and the PIN diodes 21 are formed on the same substrate, can reduce its thickness and manufacturing cost in comparison with a liquid crystal display device with a resistive type or an electrostatic capacitive type touch panel.

That is, the active matrix substrate 1 includes the plurality of transparent electrodes 15, the pixel TFTs 20 connected to the respective transparent pixel electrodes 15, and the plurality of PIN diodes 21 that flow an electric current varied depending on an amount of received light.

Note that the pixel TFT 20 is provided on each pixel of the transparent pixel electrode 15, however, the PIN diode 21 is not necessary to be provided on each pixel. Accordingly, the appropriate numbers of PIN diodes 21 may be provided on pixels so as to obtain resolution necessary for detecting a touched position.

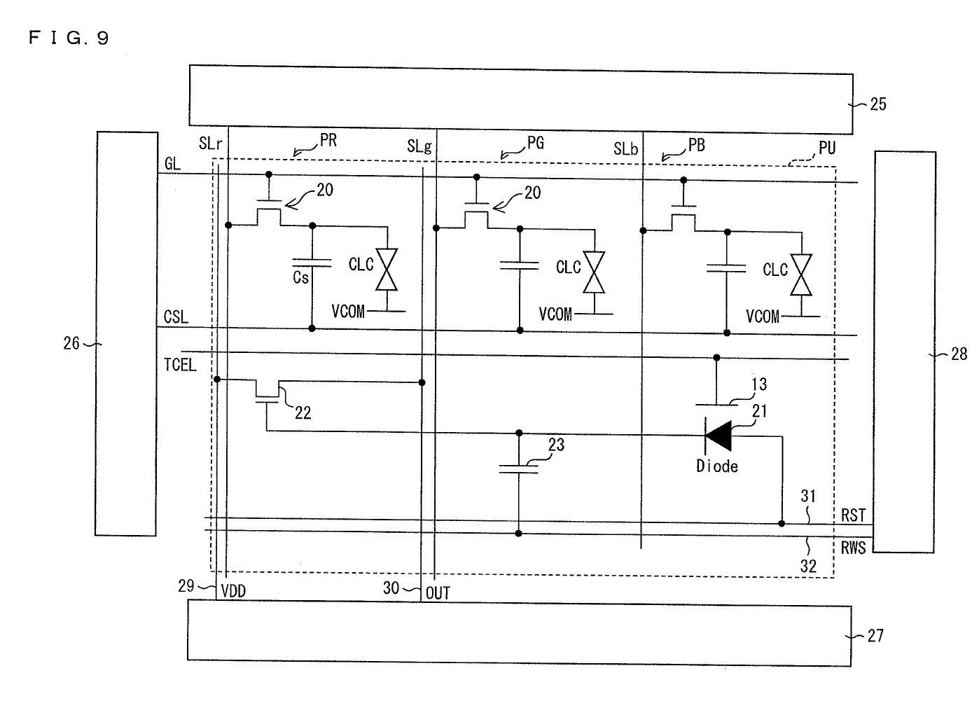

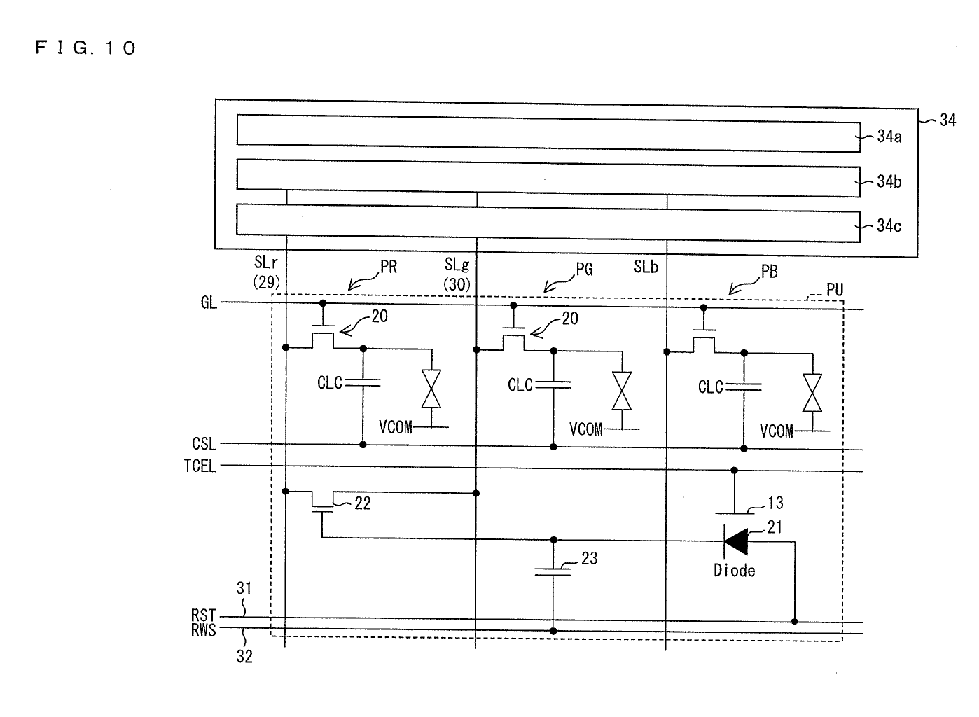

The liquid crystal display device 19 includes red, green, and blue pixels. In the present embodiment, the PIN diodes are provided on blue pixels only, and transistors, capacitors, and the like, which are connected to the PIN diodes 21, are provided on red and green pixels (See FIGS. 9 and 10 described later). However, the present invention is not limited thereto.

Note that the present embodiment employs the PIN diode 21 in which a P-layer 8e, an I-layer 8d, and an N-layer 8f are provided so as not to be laminated to one another in order to manufacture relatively easily the active matrix substrate 1 including a light receiving element serving as an optical sensor having high sensing speed. However, the present invention is not limited thereto.

It is required to use the light receiving element which flows an electric current in accordance with an amount of light received by a light receiving section of the light receiving element. Examples of the light receiving element encompass a CCD, a CMOS, a PN diode, a phototransistor, and the like.

The arrangement of the active matrix substrate 1 and a process of forming the pixel TFT 20 and the PIN diode 21 simultaneously on the active matrix substrate 1 will be described below in detail.

The present embodiment employs a glass substrate 5 as a substrate for forming the active matrix substrate 1. Note that a substrate for forming the active matrix substrate 1 is not limited to the glass substrate 5, and a quartz substrate or a plastic substrate may be employed instead.

Light shielding films 6 and 6 for preventing light of the backlight unit 4 from entering into the pixel TFT 20 and the PIN diode 21 are formed on the glass substrate 5. The Light shielding films 6 and 6 are provided to cover, from the backlight unit 4, a surface on which the pixel TFT 20 and the PIN diode 21 are formed.

A base coat film 7 is formed on both the light shielding films 6 and 6 and the glass substrate 5 so as to cover the light shielding films 6 and 6 and the glass substrate 5.

Examples of the base coat film 7 encompass a film made of an inorganic insulating substance (such as a silicon oxide film, a silicon nitride film, or a silicon oxynitride film) and a laminated film formed by appropriately combining the aforementioned films. The silicon oxide film is used in the present embodiment. These films can be formed by an LPCVD method, a plasma CVD method, a sputtering method, or the like.

The pixel TFT 20 and the PIN diode 21 are formed above the light shielding films 6 and 6 in respective regions positioned on a top surface of the base coat film 7.

That is, as illustrated in FIG. 1, the base coat film 7 is an interlayer film between the light shielding film 6 and each of the pixel TFT 20 and the PIN diode 21.

Note that a process of forming the pixel TFT 20 and the PIN diode 21 is described as follows.

First, noncrystalline semiconductor thin films, which to be polycrystalline semiconductor films 8 later, are formed above the light shielding films 6 and 6 in respective regions positioned on a top surface of the base coat film 7 by the LPCVD method, the plasma CVD method, the sputtering method, or the like.

Note that examples of the noncrystalline semiconductor thin films encompass amorphous silicon, polycrystalline silicon, amorphous germanium, polycrystalline germanium, amorphous silicon/germanium, polycrystalline silicon/germanium, amorphous silicon/carbide, polycrystalline silicon/carbide, and the like. The present embodiment employs amorphous silicon.

The noncrystalline semiconductor thin films are crystallized to thereby become the polycrystalline semiconductor films 8. A laser beam, an electron beam, or the like can be used for crystallizing the noncrystalline semiconductor thin films. The noncrystalline semiconductor thin films of the present embodiment are crystallized with use of a laser beam.

Then, the polycrystalline semiconductor films 8 are patterned by photolithography in accordance with a region in which the light shielding films 6 and 6 are formed.

Thereafter, a P-type channel 8a is formed in the middle of one polycrystalline semiconductor film 8 on a side on which the pixel TFT 20 is formed. An N-type source region 8b and an N-type drain region 8c are formed on both sides of the P-type channel 8a.

Meanwhile, the I-layer 8d, which is an intrinsic semiconductor or a semiconductor layer having low concentrations of both the P-type and the N-type impurities, is formed in the middle of another polycrystalline semiconductor film 8 on a side on which the PIN diode 21 is formed. The P-layer 8e, which is a semiconductor layer having a relatively high P-type impurity concentration, and the N-layer 8f, which is a semiconductor layer having a relatively high N-type impurity concentration, are formed on both sides of the I-layer 8d.

Next, a gate insulating film 9 formed from a silicon oxide film etc. is provided above the whole glass substrate 5, so as to cover the polycrystalline semiconductor films 8.

The present embodiment covers both the polycrystalline-pixel-TFT-20 side and the PIN-diode-21-side polycrystalline semiconductor films 8 with the gate insulating film 9, however, the gate insulating film 9 may cover only the polycrystalline-pixel-TFT-20 side semiconductor film 8 instead.

A TaN film and a W film are laminated, as an example of conductive films, on the gate insulating film 9. Note that the present embodiment employs the TaN film and the W film as the conductive films, however, the present invention is not limited thereto. The conductive films can be made of an element selected from Ta, W, Ti, Mo, Al, Cu, Cr, Nd, or the like, or an alloy material or a compound material containing one of the elements as a base. Alternatively, the conductive films may be formed by doping, with impurities such as phosphorus and boron, a semiconductor film represented by a polycrystalline silicon semiconductor or the like.

The conductive film is patterned by etching with use of a resist pattern (not illustrated) as a mask which is formed by the photolithography, and therefore become a gate electrode 10.

Next, a first inorganic insulating film 11 formed from a deposited silicon oxide film or the like is formed to cover a top surface of the gate electrode 10 and a top surface of the gate insulating film 9 (i.e., a top surface on which the gate electrode 10 is not formed).

Then, contact holes, each of which passes through the gate insulating film 9 and the first inorganic insulating film 11, are perforated on the N-type source region 8b, the N-type drain region 8c, the P-layer 8e, and the N-layer 8f.

A conductive film is formed all over a top surface of the glass substrate 5.

A conductive film made of aluminum or the like can be used as the conductive film. However, the present invention is not limited thereto, and may be alternatively made of an element selected from Ta, W, Ti, Mo, Al, Cu, Cr, Nd, etc., or an alloy material or a compound material which contains one of the elements as a base. In addition, a laminated structure can be formed, as necessary, by appropriately combining the aforementioned elements. In the present embodiment, aluminum is used.

Note that the conductive film is patterned so as to have a desired shape by etching with use of a resist pattern (not illustrated) as a mask which is formed by the photolithography, and therefore become a source electrode 12a electrically connected to the N-type source region 8b of the pixel TFT 20 and a source electrode 12b electrically connected to the N-type drain region 8c of the pixel TFT 20.

Further, the conductive film also become metal electrodes (lines) 12c, 12d electrically connected to the P-layer 8e and the N-layer 8f of the PIN diode 21, respectively.

Then, a transparent conductive film made of ITO (indium tin oxide), IZO (indium zinc oxide), or the like is formed by the sputtering method. The transparent conductive film undergoes etching with use of a photoresist, and therefore becomes a transparent cover electrode 13 provided between the metal electrodes 12c, 12d so as to cover at least I-layer 8d of the PIN diode 21 as illustrated in FIG. 1.

Next, a transparent insulating film 14 is formed by spin coating or slit coating so as to cover the first inorganic insulating film 11, the source electrode 12a, the drain electrode 12b, the metal electrodes (lines) 12c, 12d, and the transparent cover electrode 13.

Thereafter, a via hole is perforated through the transparent organic insulating film 14 on the drain electrode 12b. The via hole can be perforated by an exposure and development process in the case where the transparent organic insulating film 14 is photosensitive, meanwhile, the via hole can be perforated by, for example, dry etching method in the case where the transparent organic insulating film 14 is not photosensitive.

Note that the present embodiment employs an acrylic insulating film as the transparent organic insulating film 14.

By providing the organic insulating film as the transparent organic insulating film 14 instead of using the inorganic insulating film, a film thickness of the organic insulating film can be easily thickened by the aforementioned coating method etc. without any cracks present. In addition, the organic insulating film has generally lower dielectric constant than the inorganic insulating film, and this makes it possible to reduce a parasitic capacitance generated between the wirings (between which the organic insulating film is provided) and the electrode.

The organic insulating film can be thickened easily as described above. This makes it possible to planarize a difference in level of a lower film.

Further, the organic insulating film may contain an inorganic substance, such as siloxane polymer, as long as the organic insulating film can be thickened without any cracks present.

Finally, a transparent conductive film made of ITO, IZO, or the like is formed by the sputtering method on the transparent organic insulating film 14, and is patterned to have a desired pattern with use of a photoresist, so that the transparent pixel electrode 15 is formed.

Note that, as illustrated in FIG. 1, the transparent pixel electrode 15 is electrically connected to the drain electrode 12b.

Further, an alignment film (not illustrated) is formed on the transparent pixel electrode 15.

The transparent pixel electrode 15 and the transparent cover electrode 13 of the active matrix substrate 1 are preferably made of the same material.

According to the aforementioned arrangement, the transparent pixel electrode 15 and the transparent cover electrode 13 are made of the same material. Accordingly, it is enough to consider thicknesses of the transparent pixel electrode 15 and the transparent cover electrode 13 when they are designed in consideration of optical transparency of light having a certain wavelength. This makes it possible to manufacture relatively easily the active matrix substrate 1 including the PIN diode 21.

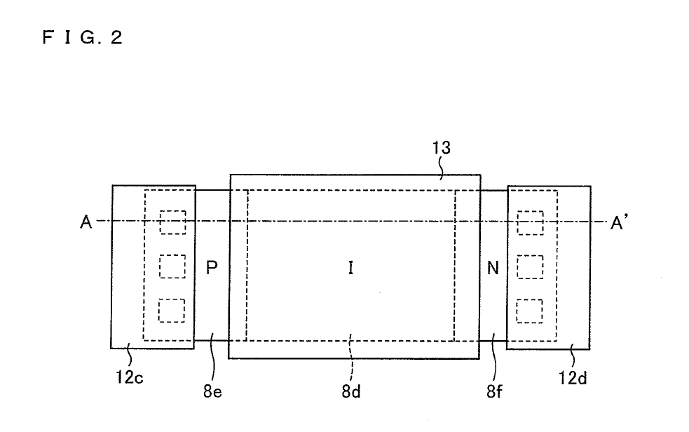

FIG. 2 is a plan view illustrating the PIN diode 21 of FIG. 1, seen from a side on which the transparent cover electrode 13 is formed.

In the present embodiment, the transparent cover electrode 13 is formed to cover the whole I-layer 8d and parts of the P-layer 8e and the N-layer 8f of the PIN diode 21 as illustrated in FIG. 2.

According to the aforementioned arrangement, the transparent cover electrode 13 is provided to cover at least the I-layer 8d corresponding to the light receiving section of the PIN diode 21. This arrangement makes it possible to minimize an adverse effect on the I-layer 8d of the PIN diode 21, which adverse effect is caused by the capacitive coupling of the electric charges accumulated in the transparent organic insulating film 14 due to a voltage applied to the transparent pixel electrode 15. Accordingly, the arrangement can accomplish the active matrix substrate 1 including the PIN diode having improved reliability.

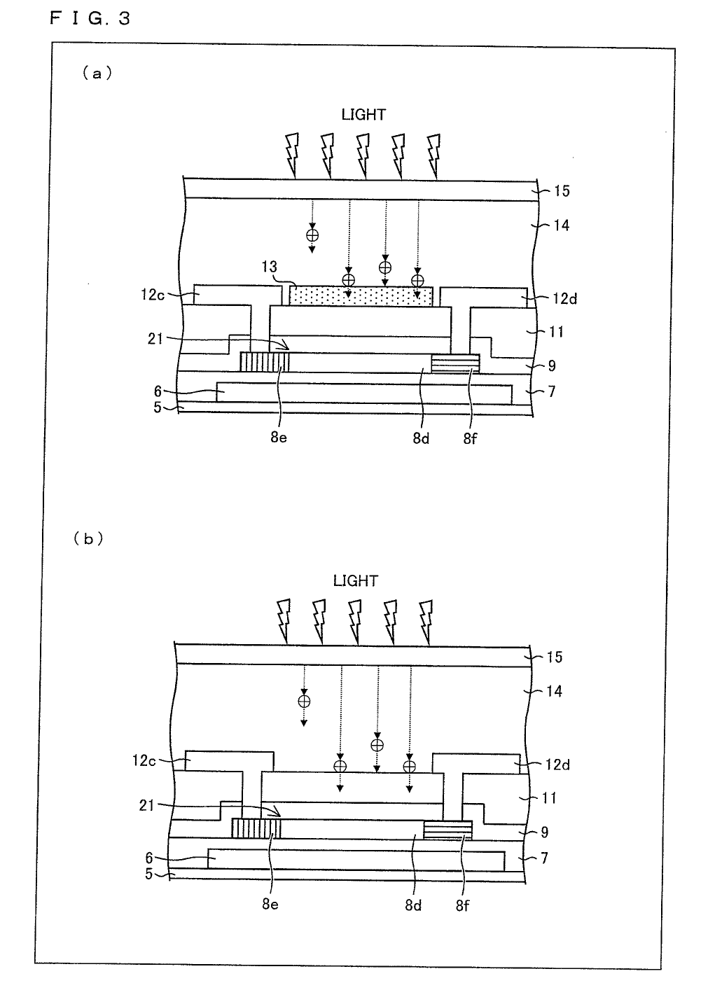

An adverse effect on the I-layer 8d of the PIN diode 21, which is affected by accumulation of the electric charges of the transparent organic insulating film 14, will be described below with reference to FIGS. 3.

FIG. 3(a) is a cross sectional view taken along the line A-A′ of FIG. 2 and illustrates a schematic arrangement of a region, which includes the PIN diode 21, in the active matrix substrate 1 of the present embodiment.

Meanwhile, FIG. 3(b) is a view of a comparative example illustrating an arrangement in which the transparent cover electrode 13 is omitted from the arrangement of FIG. 3(a).

The transparent organic insulating film 14 is not elaborated in comparison with the inorganic insulating film formed by the various kinds of CVD methods etc.

The transparent pixel electrode 15 formed on the transparent organic insulating film 14 receives a predetermined voltage for displaying an image, so that electric charges are accumulated in the transparent organic insulating film 14. The electric charges have an adverse effect on the I-layer 8d of the PIN diode 21 due to the capacitive coupling.

In order to reduce such adverse effect, the transparent electrode 13 is provided between the first inorganic insulating film 11 and the transparent organic insulating film 14 in the active matrix substrate 1 of the present invention so as to cover the I-layer 8d of the PIN diode 21 in plan view as illustrated in FIG. 3(a).

Meanwhile, the transparent cover electrode 13 is not provided in the comparative example of FIG. 3(b), so that the adverse effect cannot be reduced.

The organic insulating film, such as the transparent organic insulating film 14, cannot always keep its insulating property due to its usage environment, and sometimes generates a minute leakage current.

For example, the leakage current in the organic insulating film tends to be increased as the ambient temperature is increased.

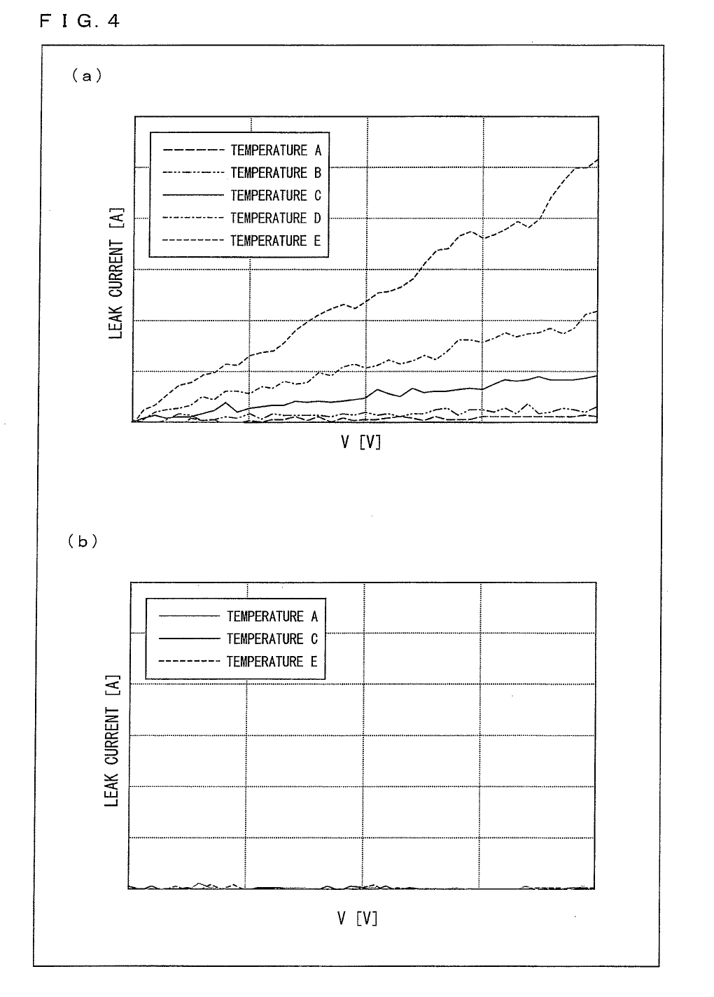

FIG. 4(a) is a view illustrating ambient temperature dependence of a leakage current in an organic insulating film; FIG. 4(b) is a view illustrating ambient temperature dependence of a leakage current in an inorganic insulating film.

As illustrated in FIG. 4(a), the leakage current in the organic insulating film increases as the ambient temperature is increased from A to E. In contrast, as illustrated in FIG. 4(b), the leakage current in the inorganic insulating film does not increase, i.e., hardly changes even if the ambient temperature is increased from A to E.

The leakage current of the transparent organic insulating film 14 for use in the present embodiment is also apt to increase as the ambient temperature is increased. This causes potential differences between the transparent pixel electrode 15 and the metal electrodes (lines) 12c, 12d and between the transparent pixel electrode 15 and the I-layer 8d. Accordingly, electric charges move into the transparent organic insulating film 14 to thereby be accumulated in the transparent organic insulating film 14.

Such electric charges accumulated in the transparent organic insulating film 14 has an adverse effect on the photocurrent characteristic of the PIN diode 21 through the following mechanism.

When the PIN diode 21 receives a predetermined voltage, a depletion-layer region is formed in the semiconductor layer of the PIN diode 21. Irradiating the depletion-layer region with light causes photoelectric effect, i.e., a photocurrent flows through the PIN diode 21.

However, a desired depletion-layer region cannot be obtained by the capacitive coupling of the electric charges accumulated in the transparent organic insulating film 14 even if the PIN diode 21 receives a predetermined voltage. Thus, a desired photocurrent cannot be obtained.

In contrast, the present embodiment can reduce the movement of the electric charges into the transparent organic insulating film 14 by providing the transparent cover electrode 13 and in addition, applying a predetermined voltage to the transparent cover electrode 13. Further, the transparent cover electrode 13 is provided closer to the PIN diode 21 than the position of the electric charges, so that the PIN diode 21 does not receive an adverse effect of the accumulated electric charges, but receives an influence of a voltage applied to the transparent cover electrode 13 (i.e., a voltage that can provide a best characteristic of the PIN diode 21 (described later in detail)).

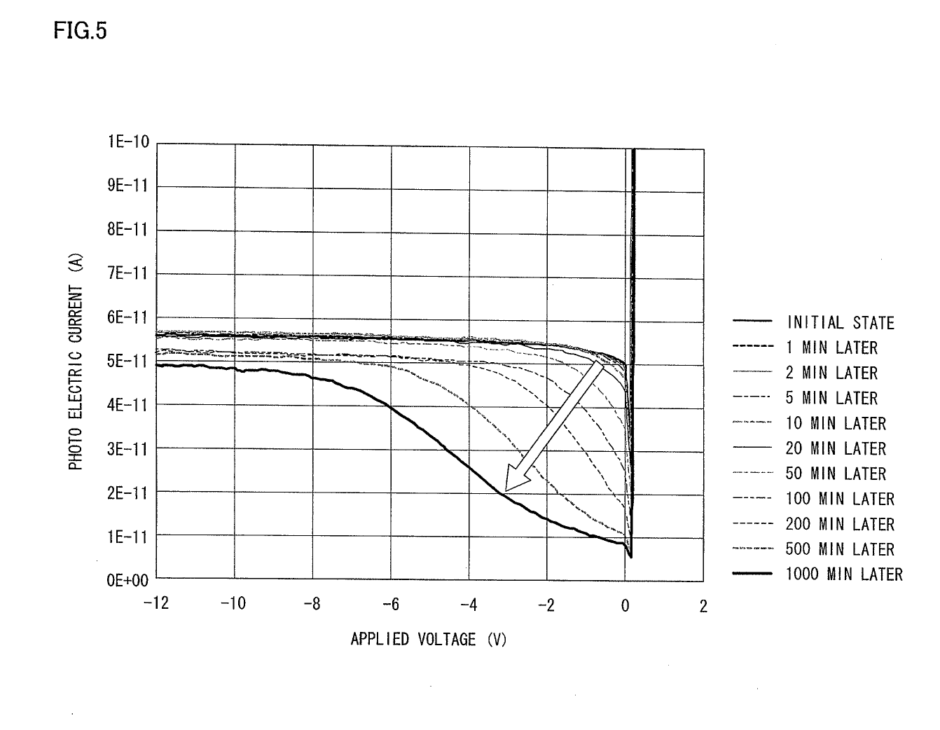

FIG. 5 is a graph showing a change over time in the photocurrent characteristic of the PIN diode 21 after an operating voltage is applied, which PIN diode 21 is of the comparative example (i.e., the arrangement in which the transparent cover electrode 13 is omitted) which is illustrated in FIG. 3(b).

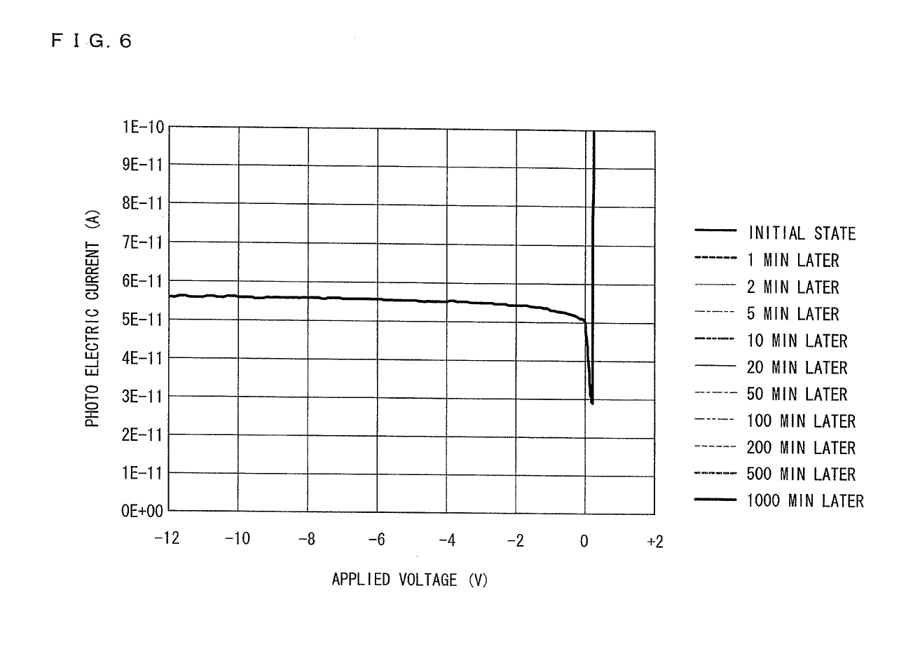

Further, FIG. 6 is a graph showing a change over time in a photocurrent characteristic of the PIN diode 21 after an operating voltage is applied, which PIN diode 21 is included in the active matrix substrate 1 of the present embodiment illustrated in FIG. 3(a).

The FIGS. 5 and 6 each indicate a result of measuring the change over time (initial state, and an irradiation time from one minute to thousand minutes) in a photodiode characteristic (a change in photocurrent with respect to a change in applied voltage) while irradiating the PIN diode 21 with light having a constant intensity. Note that the horizontal axis of FIGS. 5 and 6 denotes a voltage applied to the PIN diode 21 (minus (−) means a reverse bias), and the vertical axis denotes a photocurrent flowing through the PIN diode (“IE-10” means 1×10⁻¹⁰).

As illustrated in FIG. 5, a characteristic of the PIN diode 21 in the comparative example is deteriorated in accordance with elapsed time, for example, the photocurrent is reduced.

It is considered that the deterioration is caused by accumulation of an electric charge in the transparent organic insulating film 14 as described above.

In contrast, as illustrated in FIG. 6, reduction in photocurrent in accordance with elapsed time does not occur in the PIN diode 21 of the active matrix substrate 1 of the present embodiment.

As illustrated in FIG. 3(a), the transparent cover electrode 13 is formed between the transparent organic insulating film 14 and the I-layer 8d of the PIN diode 21 so as to cover the I-layer 8d in plan view and receives a desired voltage. This makes it possible to reduce an adverse effect (which is caused by the electric charges accumulated in the transparent organic insulating film 14) on the PIN diode 21.

Note that the photocurrent characteristic, which is obtained by applying the reverse bias to the PIN diode 21 of FIG. 6, is desired to remain unchanged no matter how much the reverse bias is applied.

In the present embodiment, the transparent cover electrode 13 is formed to cover all over the I-layer 8d as illustrated in FIG. 2, in order to maximize reduction of the adverse effect (which is caused by the electric charges accumulated in the transparent organic insulating film 14) on the PIN diode 21. However, effect of reducing the adverse effect can be obtained even when the transparent cover electrode 13 is formed to cover a part of the I-layer 8d.

Next, a condition of voltage applied to the transparent cover electrode 13 will be described.

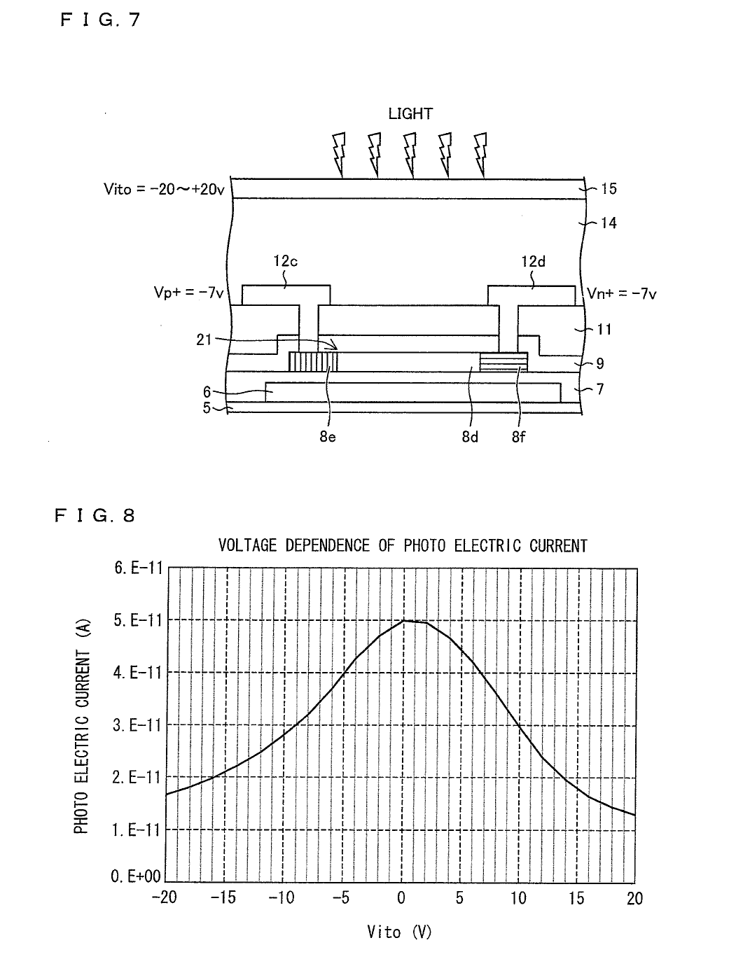

In order to determine the condition of the voltage applied to the transparent cover electrode 13, a voltage dependence of the PIN diode 21 is measured under a condition of FIG. 7. Note that an arrangement for use in this measurement is the same as that of the comparative example for the sake of easy measurement. In this arrangement, −7 V was applied to each of the metal electrodes 12c (anode of the PIN diode 21) and 12d (cathode of the PIN diode 21), and a voltage Vito of the transparent pixel electrode 15 was changed from −20 V to +20 V while irradiating the PIN diode 21 via the transparent pixel electrode 15 with a certain amount of light.

The photocurrent flowing through the PIN diode 21 was changed as illustrated in FIG. 8. It is preferable to select such a condition that the photocurrent becomes as large as possible while an amount of received light is not changed, in order to improve a detection capability of the PIN diode 21. Accordingly, the voltage Vito is preferably set within a range of the vicinity of 0 V (e.g., from −5 V to +7 V) on the basis of the measurement result (see FIG. 8).

The arrangement for use in the measurement is the same as that of the comparative example as described above. Accordingly, in the arrangement of the present embodiment added with the transparent cover electrode 13 (FIG. 3(a)), an optimum condition of the voltage to be set to the transparent cover electrode 13 may be found by changing a voltage of the transparent cover electrode 13 similarly to the voltage Vito.

Specifically, it is preferable that the transparent cover electrode 13 of the active matrix substrate 1 receives a voltage which causes the PIN diode 21 to flow an electric current as high as possible in response to a certain amount of light received by the I-layer 8d of the PIN diode 21.

An optimum voltage to be applied to the transparent cover electrode 13, which voltage causes the highest electric current to flow through the PIN diode 21, is changed as a length or thickness of the I-layer 8d of the PIN diode 21 is changed.

Because of this, a characteristic of the PIN diode 21 is further improved by adjusting a voltage applied to the transparent cover electrode 13 so as to cause an electric current as high as possible to flow through the PIN diode 21 in response to a certain amount light received by the I-layer 8d of the PIN diode 21.

Next, a circuit arrangement of the active matrix substrate 1 and a specific arrangement for applying a voltage to the transparent cover electrode 13 will be described with reference to FIGS. 9 and 10. Each of FIGS. 9 and 10 is a circuit diagram illustrating an example of a circuit arrangement of one pixel unit PU constituted by pixels PR, PG, and PB for displaying red, green, and blue, respectively, in the active matrix substrate 1 of the present embodiment.

As illustrated in FIG. 9, a source driver 25, a gate driver 26, a sensor reading driver 27, and a sensor row driver 28 are provided on an upper side, a left side, a lower side, and a right side of FIG. 9, respectively.

Intersections of a gate signal line GL connected to the gate driver 26 and source signal lines SLr, SLg, and SLb connected to the source driver 25 are positioned on respective upper regions (i.e., regions close to the source driver 25) of pixels PR, PG, PB in FIG. 9. The pixel TFTs 20 are provided in the vicinity of the respective intersections. Further, the PIN diode 21 is provided in a lower region (i.e., a region close to the sensor reading driver 27) of the blue pixel PB in FIG. 9. Further, a transistor 22 connected to the PIN diode 21 is provided in a lower region of the red pixel PR, and a capacitor 23 connected to the PIN diode 21 and the transistor 22 are provided in a lower region of the green pixel PG in FIG. 9.

The PIN diode 21, the transistor 22, and the capacitor 23 are provided in the pixels PR, PG, and PB dividedly as described above. This can prevent aperture ratios of red, green, and blue from being different largely.

Note that, in order to prolong a decay time of an electric charge which is charged to a liquid crystal capacitor CLC, a storage capacitor Cs (not illustrated in FIG. 1) is provided in the active matrix substrate 1 so as to be in parallel with a liquid crystal capacitor CLC. The storage capacitor Cs is provided between the transparent pixel electrode 15 (which is connected to the drain electrode 12b of the pixel TFT 20) and a common electrode (which faces the transparent pixel electrode 15 and receives a common electrode voltage VCOM).

One end of the storage capacitor Cs is connected to the storage capacitor bus line CSL.

Note that a source of the transistor 22 is connected to a power source supply line 29, and a drain is connected to an output signal line 30. The power source supply line 29 and the output signal line 30 are connected to the sensor reading driver 27, and the power source supply line 29 receives a power supply voltage VDD from the sensor reading driver 27.

Further, a gate of the transistor 22 is connected to a cathode of the PIN diode 21 (metal electrode 12d of FIG. 1) and is also connected to one end of the capacitor 23 connected to the PIN diode 21.

Note that an anode of the PIN diode (metal electrode 12c of FIG. 1) is connected to a reset signal line (initialization signal input line) 31 which receives a reset signal RST from the sensor row driver 28. The other end of the capacitor 23 is connected to a row selection signal line (selection signal input line) 32 which receives a row selection signal RWS. The row selection signal RWS selects a specific row and causes an output of an output signal from the specific row.

A touch panel operation based on the circuit arrangement will be described below.

According to the arrangement, the sensor row driver 28 transmits a high-level reset signal RST to the reset signal line 31 in order to reset a gate potential of the transistor 22. This transmission of the reset signal RST applies a forward bias to the PIN diode 21, so that the capacitor 23 is charged. Accordingly, the gate potential gradually rises to thereby reach an initialization potential finally.

When the reset signal RST is reduced to have a low level after the gate potential reaches the initialization potential, a cathode potential of the PIN diode 21 is higher than an anode potential, so that the PIN diode 21 is applied with a reverse bias. The gate potential herein has a value which is obtained by subtracting a forward voltage drop of the PIN diode 21 and a voltage drop caused by parasitic capacitance of the PIN diode 21 from the initialization potential.

When the PIN diode 21 is irradiated with light in the aforementioned state, a photocurrent caused by the reverse bias flows through the PIN diode 21 in accordance with the intensity of the light. Consequently, an electric charge kept in the capacitor 23 is discharged via the reset signal line 31, and therefore the gate potential is gradually lowered, and is lowered finally to a detection potential in accordance with the intensity of the light.

Next, in order to read a light detection result, a high-level row selection signal RWS is applied to the other end of the capacitor 23 from the sensor row driver 28 via the row selection signal line 32. This boosts the gate potential via the capacitor 23, so that the gate potential obtains a potential by adding a high-level potential of the row selection signal RWS to the detection potential.

The gate potential is boosted to thereby exceed a threshold voltage necessary for turning on the TFT 22, so that the TFT 22 is turned on. After that, a voltage, which is controlled on the basis of amplification factor depending on a level of the gate potential, i.e., the intensity of the light, is outputted as a detection signal from the TFT 22. The voltage is then sent to the sensor reading driver 27 via the output signal line 30.

Further, a transparent cover electrode bus line TCEL is additionally provided in the circuit arrangement of FIG. 9. The transparent cover electrode bus line TCEL is drawn into a circumferential region of the active matrix substrate 1 (i.e., a region outside the display region) so as to supply a predetermined voltage to the aforementioned transparent cover electrode 13. The transparent cover electrodes 13 provided in a plurality of pixel units PU arranged along a row direction (horizontal direction of FIG. 9) or a column direction (vertical direction of FIG. 9) can be connected to one transparent cover electrode bus line TCEL.

The optimum voltage (fixed voltage) set as described above may be applied to the transparent cover electrode bus line TCEL. For example, the transparent cover electrode bus line TCEL may be connected to the sensor row driver 28 to thereby receive the optimum voltage. Note that an electric power circuit may be additionally provided for applying a voltage to the transparent cover electrode bus line TCEL.

Note that a specific arrangement example of the transparent cover electrode bus line TCEL will be described later.

FIG. 10 is a more preferable example of the circuit arrangement of the one pixel unit PU constituted by the pixels PR, PG, and PB for displaying red, green, and blue, respectively, in the active matrix substrate 1 of the present embodiment.

In order to prevent the aperture ratios from reducing due to increase in the number of lines, the source signal line SLr and the power supply source line 29 are integrated into one line, and the source signal line SLg and the output signal line 30 are integrated into one line in the circuit arrangement as illustrated in FIG. 10.

A driving circuit 34 having functions of the source driver 25 (source signal line driving function) and the sensor reading driver 27 (sensor reading function) of FIG. 9 is provided on an upper side of FIG. 10.

The driving circuit 34 includes a shift register 34a, a sensor reading and source signal line driving circuit 34b, and a switch 34c for switching between the source signal line driving function and the sensor reading function. The source signal line SLr (serving also as power source supply line 29) and the source signal line SLg (serving also as output signal line 30) are connected to the sensor reading and source signal line driving circuit 34b via the switch 34c.

According to the aforementioned arrangement, writing into the pixel TFT 20 and reading of optical sensing data obtained by the PIN diode 21 can be carried out with use of the source signal line SLr (serving also as the power source supply line 29) and the source signal line SLg (serving also as the output signal line 30).

That is, the optical sensing data is read during a blanking period in which the writing into the pixel TFT 20 is not carried out.

The aforementioned arrangement makes it possible to largely reduce an increase in lines to thereby accomplish the active matrix substrate 1 having a high aperture ratio.

Note that the gate driver 26 and the sensor row driver 28 are omitted in FIG. 10.

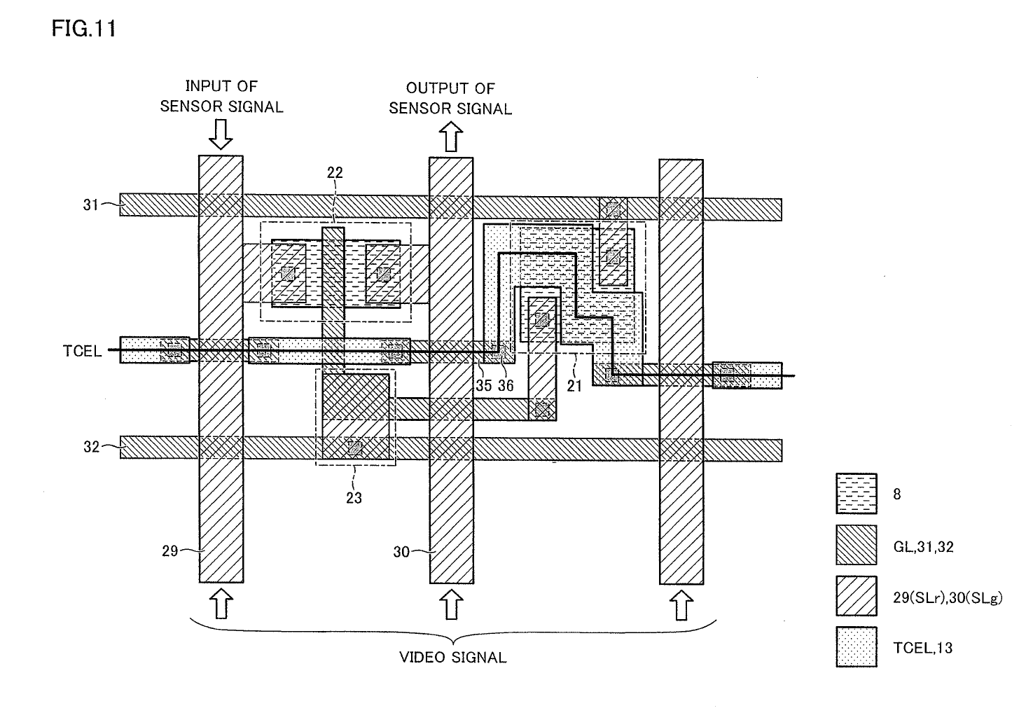

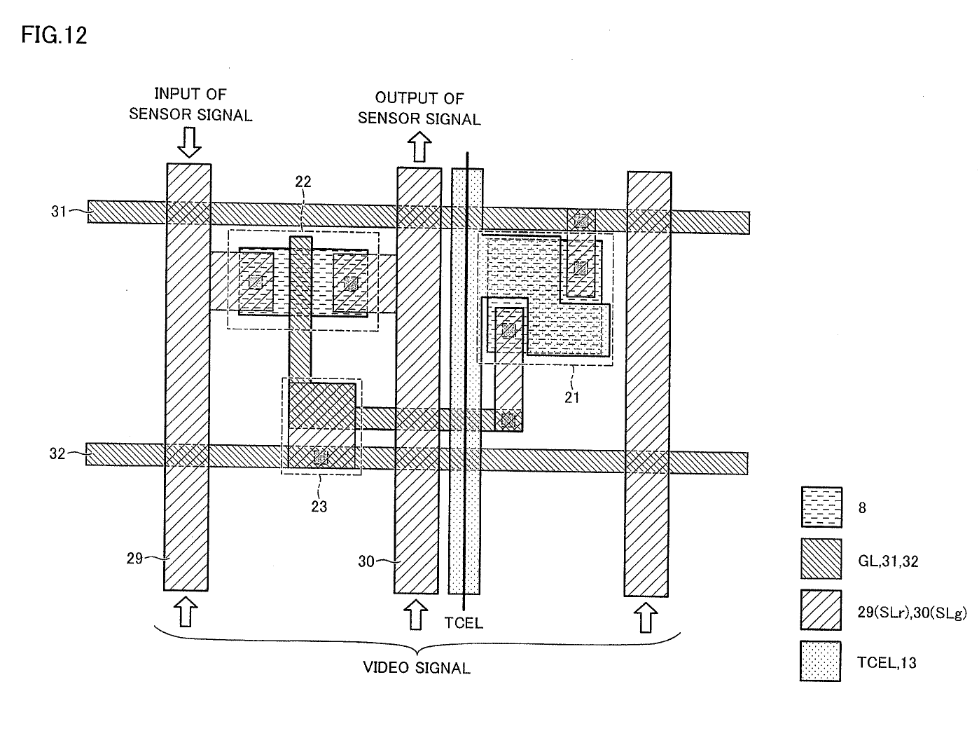

A specific arrangement example of the transparent cover electrode bus line TCEL will be described below with reference to FIGS. 11 and 12.

The transparent cover electrode 13 is provided on the same layer as the metal electrodes 12c, 12d in the arrangement of the present embodiment of FIG. 3(a). It is necessary to determine how to arrange the transparent cover electrode bus line TCEL so as not to intersect the metal electrodes 12c, 12d.

FIG. 11 is a view illustrating an example in which, in the circuit arrangement of FIG. 10, the transparent cover electrode bus line TCEL is formed along a direction in which the reset signal line 31 and the row selection signal line 32 extend.

FIG. 12 is a view illustrating an example in which, in the circuit arrangement of FIG. 10, the transparent cover electrode bus line TCEL is formed along a direction in which the source signal line SLr (serving also as the power source supply line 29) and the source signal line SLg (serving also as the output signal line 30) extend.

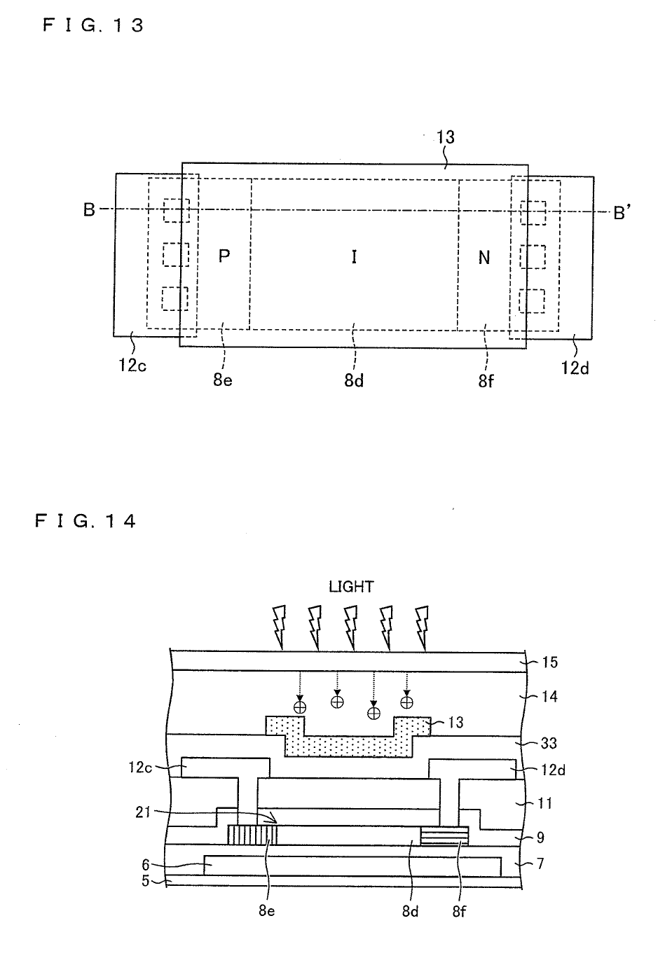

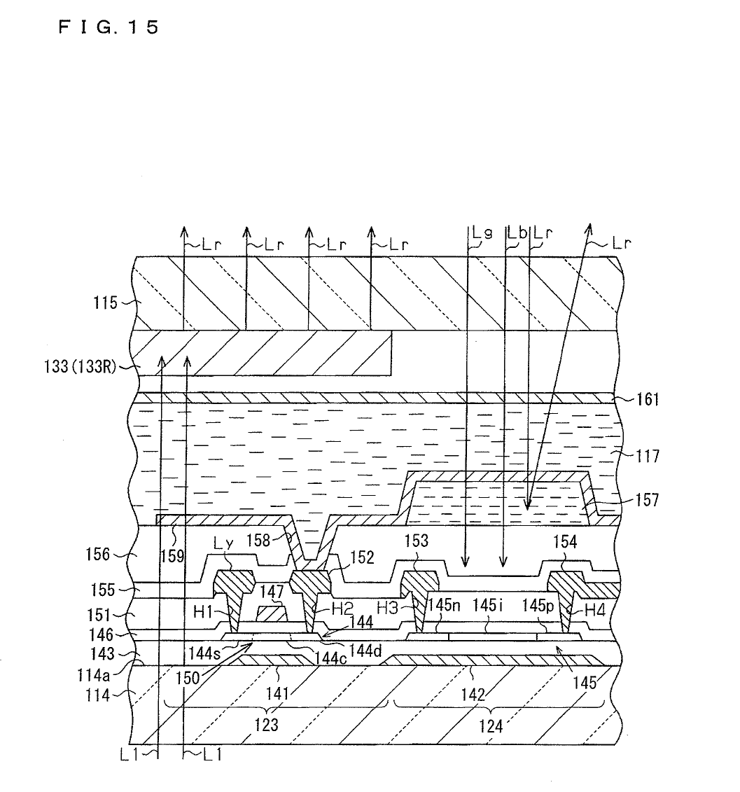

Note that, in the arrangements of FIGS. 11 and 12, the transparent cover electrode 13 which is formed to cover the I-layer of the polycrystalline semiconductor film 8 of the PIN diode 21 has a shape different from the transparent cover electrodes 13 of FIG. 2 and FIG. 13 described later. Accordingly, the metal electrodes 12c, 12d are formed into different shapes.

In the arrangement of FIG. 11, the source signal line SLr (serving also as the power source supply line 29) and the source signal line SLg (serving also as the output signal line 30) are provided on the same layer as the transparent cover electrode bus line TCEL so as not to intersect the transparent cover electrode bus line TCEL on the same layer. In areas in which the source signal lines SLr and SLg intersect the transparent cover electrode bus line TCEL, connecting line sections 35 which are formed under the signal lines SLr and SLg, i.e., on the same layer as the gate signal line GL are connected to the transparent cover electrode bus line TCEL via contact holes 36.

With this arrangement, the transparent cover electrode bus line TCEL does not intersect the source signal line SLr (serving also as the power source supply line 29) and the source signal line SLg (serving also as the output signal line 30) on the same layer, and therefore can be formed along a direction in which the reset signal line 31 and the row selection signal line 32 extend.

Further, in the arrangement of FIG. 12, the transparent cover electrode bus line TCEL is formed in parallel with the source signal line SLr (serving also as the power source supply line 29) and the source signal line SLg (serving also as the output signal line 30) so as not to intersect the signal lines SLr and SLg.

Accordingly, the transparent cover electrode bus line TCEL does not intersect the source signal line SLr (serving also as the power source supply line 29) and the source signal line SLg (serving also as the output signal line 30) on the same layer, and therefore can be formed along a direction in which the source signal line SLr (serving also as the power source supply line 29) and the source signal line SLg (serving also as the output signal line 30) extend.

Further, needless to say, the aforementioned arrangement example is applicable to the arrangement of FIG. 9.

Note that, in an arrangement of FIG. 14 described later, the metal electrodes 12c, 12d and the transparent cover electrode bus line TCEL are electrically insulated even when intersecting each other, so that the transparent cover electrode bus line TCEL is arranged more easily.

In the present embodiment, each of the drivers 25, 26, 27, and 28 can be monolithically formed on the active matrix substrate 1 with use of the polycrystalline semiconductor film 8 having relatively higher electron mobility.

The active matrix substrate 1, which is arranged as described above, is included in the liquid crystal display device 19, so that the present invention can accomplish a high-reliable liquid crystal display device 19 having a bright display quality and a touch panel function (area sensor function).

### Embodiment 2

Next, Embodiment 2 of the present invention will be described with reference to FIGS. 13 and 14. The present embodiment is different from Embodiment 1 in that a second inorganic insulating film 33 is provided between the transparent cover electrode 13 and the metal electrodes 12c, 12d connected to the PIN diode 21 via the first inorganic insulating film 11. The rest of arrangement of Embodiment 2 is the same as that of Embodiment 1. For the sake of easy explanation, members and configurations having the like functions as the figures described in Embodiment 1 are denoted by the like symbols, and therefore the detailed description thereof is omitted.

FIG. 13 is a plan view illustrating the PIN diode 21 provided in the display panel substrate of the present embodiment, seen from a side on which the transparent cover electrode 13 is formed.

Further, FIG. 14 is a cross sectional view taken along the line B-B′ line of FIG. 13, and illustrates a schematic arrangement of a region in which the PIN diode 21 is formed in the display panel substrate of the present embodiment.

As illustrated in FIGS. 13 and 14, the second inorganic insulating film 33 is provided between the transparent cover electrode 13 and the metal electrodes 12c, 12d connected to the PIN diode 21. This make it possible to partially superimpose the transparent cover electrode 13 and each of the metal electrodes 12c, 12d as illustrated in FIG. 13.

It is therefore possible to prevent short circuit more surely, which is caused by alignment shift etc. between the transparent cover electrode 13 and the metal electrodes 12c, 12d, so that the present invention can accomplish the display panel substrate having improved reliability.

Further, the inorganic insulating film 33 is provided between the metal electrodes 12c, 12d and the transparent cover electrode bus line TCEL, so that electrical insulation therebetween can be kept even if the metal electrodes 12c, 12d and the transparent cover electrode bus line TCEL (see FIGS. 9 and 10) intersect each other as described above. It is therefore possible to provide the transparent cover electrode bus line TCEL so as to intersect the metal electrodes 12c, 12d. This allows an easy arrangement of the transparent cover electrode bus line TCEL.

Note that the second inorganic insulating film 33 is provided similarly to the first inorganic insulating film 11, and therefore the description thereof is omitted.

As described above, a display panel substrate (active matrix substrate 1) of the present invention includes a plurality of pixels, the display panel substrate including, in a pixel: a light receiving element (PIN diode 21) for flowing therethrough a different electric current in accordance with an amount of light received by the light receiving element, a first inorganic insulating film (first inorganic insulating film 11) formed on the light receiving element, a line (metal electrodes 12c, 12d) being formed on or above the first inorganic insulating film and being electrically connected to the light receiving element, an organic insulating film (transparent organic insulating film 14) formed on or above the line, a transparent pixel electrode (transparent pixel electrode 15) formed on the organic insulating film, and a transparent electrode (transparent cover electrode 13), which is provided at such a position that the transparent electrode is located between the organic insulating film and the first inorganic insulating film and is formed to cover at least a part of a light receiving section of the light receiving element.

Further, the display panel substrate (active matrix substrate 1) of the present invention includes: a light receiving element (PIN diode 21) for flowing therethrough a different electric current in accordance with an amount of light received by the light receiving element; an organic insulating film (transparent organic insulating film 14) formed on a light path of the light incident on the light receiving element; and a transparent electrode (transparent cover electrode 13) formed on the light path so as to be between the light receiving element and the organic insulating film is.

Furthermore, the transparent electrode of the present invention includes, between the light receiving element and the organic insulating film, at least a part of a layer serving as a conductive section while keeping at least a part of the light path.

The display panel substrate of the present invention further preferably includes a transparent electrode bus line which is electrically connected to the transparent electrode and extends outside a display region of the display panel substrate.

According to the aforementioned arrangement, a predetermined voltage is applied to the transparent electrode by supplying power to an end of the transparent electrode bus line which is drawn outside the display region of the display panel substrate. This arrangement makes it possible to reduce an adverse effect on the light receiving element, which adverse effect is caused by the capacitive coupling.

It is preferable that the transparent electrode bus line is electrically connected to the transparent electrodes, which are provided to the plurality of pixels, respectively, and supplies electric power to the plurality of transparent electrodes collectively.

In the display panel substrate of the present invention, the transparent electrode preferably covers the whole light receiving section.

The transparent electrode is provided to cover the whole light receiving section of the light receiving element, so that the aforementioned arrangement can more effectively reduce an adverse effect (caused by the capacitive coupling) on the light receiving section of the light receiving element, and therefore the present invention can accomplish the display panel substrate including the light receiving element having improved reliability.

The display panel substrate of the present invention preferably further includes a second inorganic insulating film provided between the transparent electrode and the line.

According to the aforementioned arrangement, the second inorganic insulating film is provided between the transparent electrode and the line. This makes it possible to more surely prevent short circuit caused by alignment shift etc. between the transparent electrode and the line, and therefore the present invention can accomplish the display panel substrate having improved reliability.

Further, in the aforementioned arrangement, the line and the transparent electrode can be arranged freely, without reference to superimposing of the line and the transparent electrode.

In the display panel substrate of the present invention, the light receiving element is preferably a photodiode including (i) a P-layer which is a semiconductor layer having a relatively high P-type impurity concentration, (ii) an I-layer which is an intrinsic semiconductor or a semiconductor layer having a relatively low impurity concentration, and (iii) an N-layer which is a semiconductor layer having a relatively high N-type impurity concentration; and the light receiving section is preferably the I-layer.

In the display panel substrate of the present invention, the P-layer, the I-layer, and the N-layer are preferably aligned to one another along an in-plane direction.

According to the aforementioned arrangement, the P-layer, the I-layer, and the N-layer are not laminated on one another. This makes it possible to reduce a parasitic capacitance between any two layers and improve a sensing speed of an optical sensor.

Further, the photodiode can be easily made by the same manufacturing process as an active element such as TFT (Thin Film Transistor) element.

Accordingly, the display panel substrate including a light receiving element having a high sensing speed can be made relatively easily.

In the display panel substrate of the present invention, the transparent pixel electrode and the transparent electrode are preferably made of a same material.

According to the aforementioned arrangement, the transparent pixel electrode and the transparent electrode are made of the same material. Accordingly, it is enough to consider thicknesses of the transparent pixel electrode and the transparent electrode when they are designed in consideration of optical transparency of light having a certain wavelength. This makes it possible to manufacture relatively easily the display panel substrate including a light receiving element.

The present invention is not limited to the description of the embodiments above, and may be modified in numerous ways by a skilled person as long as such modification falls within the scope of the claims. An embodiment based on a proper combination of technical means disclosed in different embodiments is encompassed in the technical scope of the present invention.

The present invention is applicable to a display device represented by a liquid crystal display device or an organic EL display device.

1. A display panel substrate including a plurality of pixels, a pixel in the display panel substrate comprising:
a light receiving element for conducting therethrough a different electric current in accordance with an amount of light received by the light receiving element,
a first inorganic insulating film formed on or above the light receiving element,
a line formed on or above the first inorganic insulating film and electrically connected to the light receiving element,
an organic insulating film formed on or above the line,
a transparent pixel electrode formed on or above the organic insulating film, and
a transparent electrode provided at such a position that the transparent electrode is located between the organic insulating film and the first inorganic insulating film so as to cover at least a part of a light receiving section of the light receiving element.

2. The display panel substrate according to claim 1, further comprising:
a transparent electrode bus line which is electrically connected to the transparent electrode and extends outside a display region of the display panel substrate.

3. The display panel substrate according to claim 1, wherein the transparent electrode covers the whole light receiving section.

4. The display panel substrate according to claim 1, further comprising:
a second inorganic insulating film provided between the transparent electrode and the line.

5. The display panel substrate according to claim 1, wherein:
the light receiving element is a photodiode including (i) a P-layer which is a semiconductor layer having a relatively high P-type impurity concentration, (ii) an I-layer which is an intrinsic semiconductor or a semiconductor layer having a relatively low impurity concentration, and (iii) an N-layer which is a semiconductor layer having a relatively high N-type impurity concentration; and
the light receiving section is the I-layer.

6. The display panel substrate according to claim 5, wherein:
the P-layer, the I-layer, and the N-layer are aligned to one another along an in-plane direction.

7. The display panel substrate according to claim 1, wherein:
the transparent pixel electrode and the transparent electrode are made of a same material.

8. A display panel substrate, comprising:
a light receiving element for conducting therethrough a different electric current in accordance with an amount of light received by the light receiving element;
an organic insulating film formed on a light path of the light incident on the light receiving element; and
a transparent electrode formed on the light path so as to be between the light receiving element and the organic insulating film.

9. A display device, comprising:
the display panel substrate according to claim 1.

10. A display device, comprising:
the display panel substrate according to claim 8.
